(19) United States
(12) Patent Application Publication
(10) Pub. No.: US 2017/0062276 A1
(43) Pub. Date: Mar. 2, 2017

(54) Semiconductor Device with Contact Structures Extending Through an Interlayer and Method of Manufacturing

(71) Applicant: Infineon Technologies Dresden GmbH, Dresden (DE)

(72) Inventors: Stefan Tegen, Dresden (DE); Martin Bartels, Dresden (DE); Thomas Bertrams, Dresden (DE); Marko Lemke, Dresden (DE); Rolf Weis, Dresden (DE)

(21) Appl. No.: 15/249,008

(22) Filed: Aug. 26, 2016

(30) Foreign Application Priority Data
Aug. 28, 2015 (DE) 102015114405.0

(51) Int. Cl. H01L 21/768; H01L 29/40; H01L 23/535; H01L 29/10; H01L 29/78; H01L 29/66; H01L 29/06

(52) U.S. Cl. CPC H01L 21/76897; H01L 29/66696; H01L 29/66704; H01L 29/408; H01L 29/0696; H01L 29/1095; H01L 29/7825; H01L 21/76805; H01L 21/76834; H01L 21/76832; H01L 23/535

(57) ABSTRACT

A layer stack is formed on a main surface of a semiconductor layer, wherein the layer stack includes a dielectric capping layer and a metal layer between the capping layer and the semiconductor layer. Second portions of the layer stack are removed to form gaps between remnant first portions. Adjustment structures of a second dielectric material are formed in the gaps. An interlayer of the first or a third dielectric material is formed that covers the adjustment structures and the first portions. Contact trenches are formed that extend through the interlayer and the capping layer to metal structures formed from remnant portions of the metal layer in the first portions, wherein the capping layer is etched selectively against the auxiliary structures.

### BACKGROUND

The application refers to semiconductor devices such as power semiconductor switches as well as methods of manufacturing semiconductor devices.

In IGFETs (insulated gate field effect transistors) a gate potential applied to a gate electrode controls the minority charge carrier distribution in adjoining channel portions, wherein in an on-state of the IGFET an inversion layer of minority charge carriers forms a conductive channel through which a load current flows between a source region and a drain region. Distributing the transistor functionality across a plurality of transistor cells arranged in parallel increases the total channel width. For example, a lithography process at an exposure wavelength of 193 nm allows for a center-to-center distance of 100 nm and less between neighboring stripe-shaped transistor cells. For transistor cells with the source and drain regions contacted from the same side, increasing the population density of transistor cells involves shrinking lateral distances between drain regions and contacts to source regions as well as between source regions and contacts to drain regions.

There is a need to improve a trade-off between yield and reliability for the manufacture of semiconductor devices.

### SUMMARY

According to an embodiment, a method of manufacturing a semiconductor device includes forming a layer stack on a main surface of a semiconductor layer. The layer stack includes a dielectric capping layer and a metal layer between the capping layer and the semiconductor layer. Second portions of the layer stack are removed to form gaps between remnant first portions of the layer stack. Adjustment structures of a second dielectric material are formed in the gaps. An interlayer of the first or a third dielectric material is formed that covers the adjustment structures and the first portions of the layer stack. Contact trenches are formed that extend through the interlayer and the capping layer to metal structures which are formed from remnant portions of the metal layer in the first portions of the layer stack, wherein the capping layer is selectively etched against the auxiliary structures.

According to another embodiment a semiconductor device includes separated layered stacks on a first surface of a semiconductor portion. Each layered stack includes a cap of a first dielectric material and a metal structure between the cap and the semiconductor portion. Auxiliary structures of a second dielectric material are between neighboring layered stacks. An interlayer of the first or a third dielectric material covers the layered stacks and the auxiliary structures. Contact structures extend through the interlayer and the caps to the metal structures in the layered stacks, wherein between neighboring auxiliary structures the contact structures include first portions extending through the caps.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the invention and are incorporated in and constitute a part of this specification. The drawings illustrate the embodiments of the present invention and together with the description serve to explain principles of the invention. Other embodiments of the invention and intended advantages will be readily appreciated as they become better understood by reference to the following detailed description.

FIG. 1A is a schematic vertical cross-sectional view through a portion of a semiconductor substrate for illustrating a method of manufacturing a semiconductor device according to an embodiment using auxiliary structures formed in gaps in a layer stack, after forming a first mask.

FIG. 1B is a schematic vertical cross-sectional view of the semiconductor substrate portion of FIG. 1A, after forming gaps in the layer stack.

FIG. 1C is a schematic vertical cross-sectional view of the semiconductor substrate portion of FIG. 1B, after forming auxiliary structures in the gaps.

FIG. 1D is a schematic vertical cross-sectional view of the semiconductor substrate portion of FIG. 1C, after forming a second mask on an interlayer covering the auxiliary structures and the first portions of the layer stack.

FIG. 1E is a schematic vertical cross-sectional view of the semiconductor substrate portion of FIG. 1D, after forming contact trenches extending through the interlayer to metal structures in the first portions of the layer stack.

FIG. 1F is a schematic vertical cross-sectional view of the semiconductor substrate portion of FIG. 1E after forming contact structures in the contact trenches.

FIG. 1G is a schematic plan view of the semiconductor substrate portion of FIG. 1F according to an embodiment.

FIG. 2 is a schematic vertical cross-sectional view of a portion of a semiconductor device according to a reference example without auxiliary structures and capping layer for discussing background useful for understanding the embodiments.

FIG. 3A is a schematic cross-sectional view of a portion of a semiconductor substrate for illustrating a method of manufacturing a semiconductor device with auxiliary structures and a low-permittivity layer, after forming gaps between first portions of a layer stack.

FIG. 3B is a schematic horizontal cross-sectional view of the semiconductor substrate portion of FIG. 3A, after forming the low-permittivity layer.

FIG. 3C is a schematic horizontal cross-sectional view of the semiconductor substrate portion of FIG. 3B, after forming the auxiliary structures and an interlayer.

FIG. 3D is a schematic horizontal cross-sectional view of the semiconductor substrate portion of FIG. 3C, after forming contact trenches extending through the interlayer to metal structures in the first portions of the layer stack.

FIG. 4A is a schematic cross-sectional view of a portion of a semiconductor substrate for illustrating a method of manufacturing a semiconductor device with an auxiliary structure based on a conformal auxiliary layer, after forming gaps between first portions of a layer stack.

FIG. 4B is a schematic cross-sectional view of the semiconductor substrate portion of FIG. 4A, after forming the auxiliary layer.

FIG. 4C is a schematic cross-sectional view of the semiconductor substrate portion of FIG. 4B, after forming an interlayer filling voids left in the gaps after deposition of the auxiliary layer.

FIG. 4D is a schematic cross-sectional view of the semiconductor substrate portion of FIG. 4C, after forming contact trenches extending through the interlayer to metal structures in the first portions of the layer stack.

FIG. 5 is a schematic cross-sectional view of a portion of a semiconductor device according to an embodiment including transistor cells with the source and drain zones arranged side-by-side as well as separated auxiliary structures.

FIG. 6 is a schematic cross-sectional view of a portion of a semiconductor device according to an embodiment including transistor cells with the source and drain zones arranged side-by-side as well as a low-permittivity layer between auxiliary structures and layered stacks including metal structures.

FIG. 7 is a schematic cross-sectional view of a portion of a semiconductor device according to an embodiment including transistor cells with the source and drain zones arranged side-by-side as well as auxiliary structures based on a conformal auxiliary layer.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open, and the terms indicate the presence of stated structures, elements or features but do not preclude additional elements or features. The articles “a”, an and the are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor. The term “electrically coupled” includes that one or more intervening element(s) adapted for signal transmission may be provided between the electrically coupled elements, for example elements that are controllable to temporarily provide a low-ohmic connection in a first state and a high-ohmic electric decoupling in a second state.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

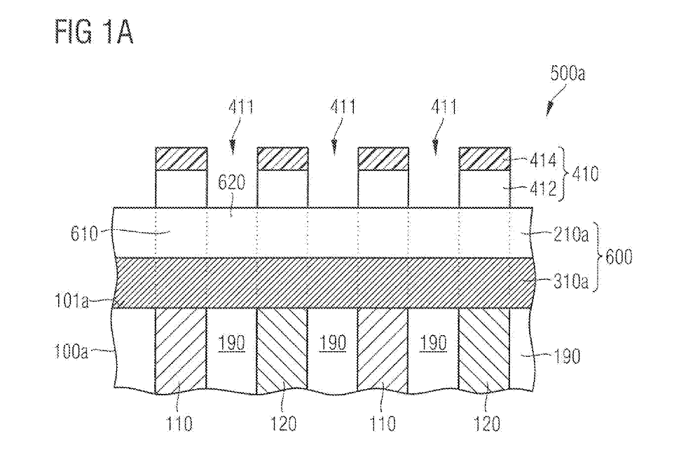

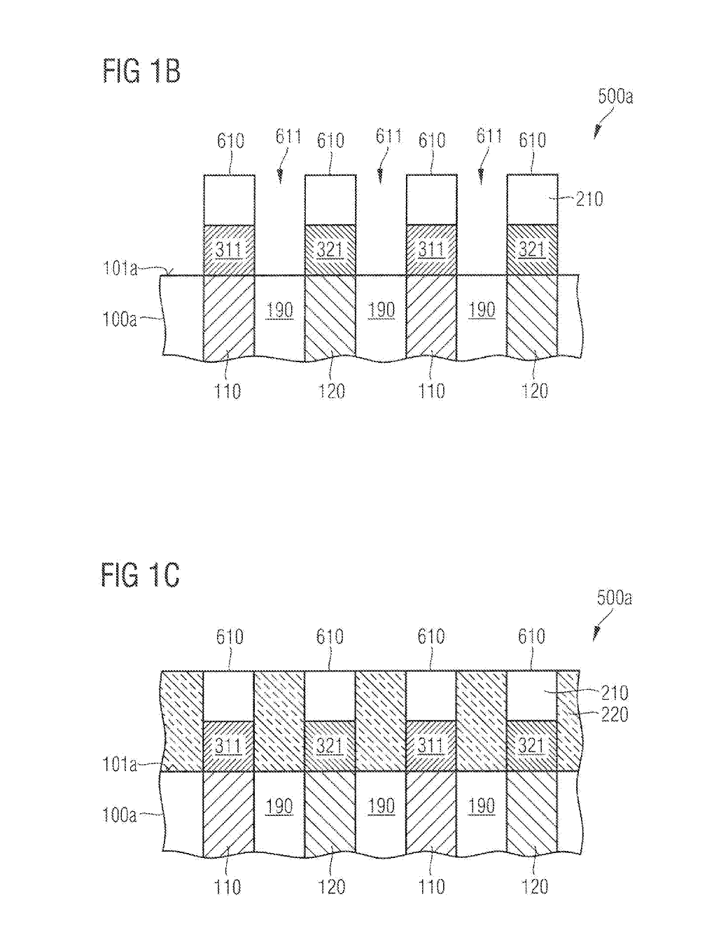

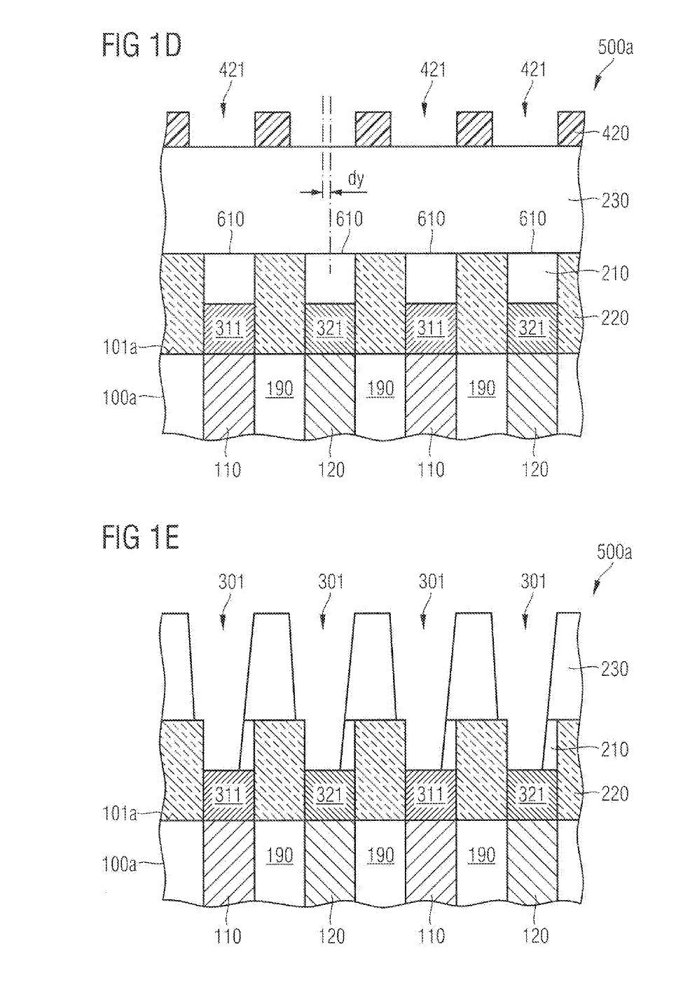

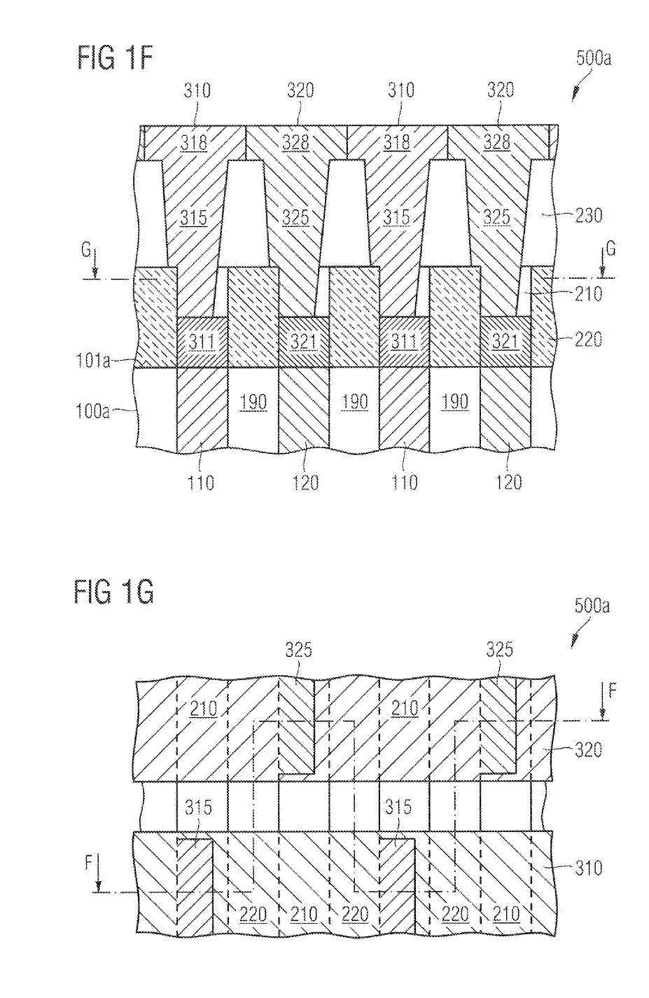

FIGS. 1A to 1G refer to a method of manufacturing a semiconductor device, wherein auxiliary structures between metal structures laterally confine contact trenches exposing the metal structures.

FIG. 1A shows a semiconductor substrate 500a that includes a semiconductor layer 100a of a semiconductor material. The semiconductor substrate 500a may be a semiconductor wafer from which a plurality of identical semiconductor dies is obtained. The semiconductor material may be crystalline silicon (Si), silicon carbide (SiC), germanium (Ge), a silicon germanium crystal (SiGe), gallium nitride (GaN), gallium arsenide (GaAs) or any other A_{III}B_{V} semiconductor, by way of example.

A perpendicular to a planar main surface 101a of the semiconductor layer 100a defines a vertical direction. Directions orthogonal to the vertical direction are horizontal directions.

In the semiconductor layer 100a first and second conductive structures 110, 120 are formed, which may be or include heavily doped single-crystalline or polycrystalline semiconducting portions or structures including metals or conductive metal compounds.

A metal layer 310a is deposited above the main surface 101a and a dielectric capping layer 210a is formed above the metal layer 310a.

A first mask layer may be deposited on a layer stack 600 that includes at least the metal layer 310a and the capping layer 210a. The first mask layer is patterned by photolithography to form a first mask 410.

FIG. 1A shows the first mask 410 formed on the layer stack 600, which covers the main surface 101a of the semiconductor layer 100a including the first and second conductive structures 110, 120 as well as insulator structures 190 separating and insulating neighboring first and second conductive structures 110, 120 from each other.

The first and second conductive structures 110, 120 may be electrically connected to different electrodes of electronic elements formed in the semiconductor layer 100a. For example, the first conductive structures 110 may be source zones or source plugs connected to the source zones of an IGFET and the second conductive structures 120 may be drain zones or drain plugs connected to the drain zones of the IGFET. According to other embodiments, the first conductive structures 110 may be emitter zones or emitter plugs connected to the emitter zones of a BJT (bipolar junction transistor) and the second conductive structures 120 may be collector zones or collector plugs connected to the collector zones of the BJT. According to further embodiments, the first conductive structures 110 may be anode zones or anode electrodes and the second conductive structures 120 may be cathode zones or cathode electrodes of a semiconductor diode or a capacitor at least partially formed in the semiconductor layer 100a. At least some of the first and second conductive structures 110, 120 may alternate along at least one lateral direction or along two lateral directions.

The insulator structures 190 separate and insulate neighboring first and second conductive structures 110, 120 from each other. The insulator structures 190 may be completely formed from one or more dielectric material(s) or may include dielectric, semiconducting and/or conductive structures in addition to dielectric structures. According to an embodiment, the insulator structures 190 are homogeneous structures of one single dielectric material, for example a semiconductor oxide such as silicon oxide, a semiconductor oxynitride such as silicon oxynitride, a semiconductor nitride such as a silicon nitride, undoped or doped silicate glass, such as BSG (boron silicate glass), PSG (phosphorus silicate glass), BPSG (boron phosphorus silicate glass), or FSG (fluorosilicate glass). According to other embodiments, the insulator structures 190 include two or more layers of different materials, wherein at least one of the materials is a dielectric material. For example, the insulator structures 190 may be trench electrode structures including a conductive electrode insulated from the semiconductor material of the semiconductor layer 100a.

The layer stack 600 includes at least the dielectric capping layer 210a and the metal layer 310a, which is formed between the capping layer 210a and the semiconductor layer 100a. According to the illustrated embodiment the metal layer 310a is sandwiched between the capping layer 210a and the semiconductor layer 100a and directly adjoins to both the capping layer 210a and the semiconductor layer 100a. According to other embodiments, the layer stack 600 may include one or more further layers between the capping layer 210a and the metal layer 310a and/or between the metal layer 310a and the semiconductor layer 100a.

At least a main portion of the capping layer 210a or the complete capping layer 210a is formed from a first dielectric material, which may have a low permittivity εr of less than 4.5 or 4.0 and which etch characteristics are close to deposited silicon oxide. For example, the capping layer 210a may be a single layer or a combination of at least two layers each selected from deposited silicon oxide, e.g., TEOS silicon oxide based on TEOS (tetraethylorthosilicate) as precursor material, silicon oxynitride, BSG, PSG, BPSG, or FSG.

The metal layer 310a may be a layer from heavily doped polycrystalline silicon, and/or may include one or more metal-containing layers of one or more metals such as aluminum (Al), copper (Cu), titanium (Ti), tungsten (W), tantalum (Ta), gold (Au), or silver (Ag).

The first mask 410 may be based on a mask layer stack including a photoresist layer 414 of a light-sensitive material and an auxiliary mask layer 412 of a material against which the material of the capping layer 210a may be etched with high selectivity. For example, the capping layer 210a is a silicon oxide layer and the auxiliary mask layer 412 is or includes a layer of silicon nitride, polycrystalline silicon, amorphous silicon or carbon. First mask openings 411 in the first mask 410 are formed in the vertical projection of the insulator structures 190.

Using the first mask 410 as an etch mask, second portions 620 of the layer stack 600 in the vertical projection of the first mask openings 411 and the first mask 410 are removed, wherein the capping layer 210a may be used as a hard mask for patterning the metal layer 310a such that the capping layer 210a may be partially consumed and a vertical extension of the capping layer 210a after patterning the layer stack 600 may be smaller than that of the capping layer before etching the layer stack 600.

FIG. 1B shows remnant first portions of the layer stack 600 of FIG. 1A forming isolated layered stacks 610. Gaps 611 in the layer stack 600 are formed in the vertical projection of the insulator structures 190. The layered stacks 610 are in the vertical projection of the first and second conductive structures 110, 120. The layered stacks 610 may overlap with the insulator structures 190 on at least one side and/or the gaps 611 may overlap with the first and second conductive structures 110, 120 on at least one side to some degree, respectively.

In the layered stacks 610 remnants of the capping layer 210a form dielectric caps 210 on remnants of the metal layer 310a, which form first metal structures 311 electrically connected or directly adjoining the first conductive structures 110 as well as second metal structures 321 electrically connected or directly adjoining the second conductive structures 120. The layered stacks 610 may be parallel stripes.

Auxiliary structures 220 are formed in the gaps 611 of the layer stack 600 between the layered stacks 610. Forming the auxiliary structures 220 may include deposition of a dielectric material, which etch resistivity significantly differs from that of the first dielectric material of the caps 210. Forming the auxiliary structure 220 may include deposition of a conformal layer of the second dielectric material or a gap filling process.

FIG. 1C shows the auxiliary structures 220 between the layered stacks 610. The auxiliary structure 220 may completely fill the space between neighboring layered stacks 610 or may at least partially fill the space between the layered stacks 610, wherein in the vertical direction the auxiliary structure 220 extends at least between an interface between the cap 210 and the metal structures 311, 321 and a surface of the caps 210 opposite to the metal structures 311, 321. The auxiliary structure 220 may exclusively be formed between the layered stacks 610. According to another embodiment, the auxiliary structures 220 are portions of a comb-like structure resulting from a deposition process and including both fill portions between the layered stacks 610 and a layer portion above the layered stacks 610.

An interlayer 230 is deposited over the auxiliary structures 220 and the layered stacks 610. A second mask layer may be deposited on an exposed surface of the interlayer 230 and patterned by photolithography to form a second mask 420.

FIG. 1D shows the second mask 420 with second mask openings 421 in the vertical projection of the layered stacks 610, wherein a horizontal extension of the second mask openings 421 may be equal to or greater than a corresponding horizontal extension of the layered stacks 610. The second mask 420 is depicted at a slight misalignment dy between central axes of the second mask openings 421 and central axes of the layered stacks 610.

The interlayer 230 may have a vertical extension in a range from 100 nm to 5 μm and may be of the first dielectric material 210 or another, third dielectric material, which has a high etch selectivity against the second dielectric material defining the etch characteristics of the auxiliary structures 220.

Using the second mask 420 as an etch mask, contact trenches 301 are etched through the interlayer 230 and through the caps 210 down to at least a surface of the first and second metal structures 311, 321. The etch is highly selective against the second dielectric material such that the auxiliary structures 220 laterally confine bottom sections of the contact trenches 301 between neighboring auxiliary structures 220 and directly adjoining to the first and second metal structures 311, 321.

FIG. 1E shows the contact trenches 301 at the misalignment dy between the second mask openings 421 and the layered stacks 610 as illustrated in FIG. 1D. The auxiliary structures 220 ensure that a lateral distance between first metal structures 311 and contact trenches 301 to second metal structures 321 as well as between second metal structures 321 and contact trenches 301 to first metal structures 311 do not fall below a minimum distance given by the lateral dimension of the auxiliary structures 220.

The second mask 420 may be removed and separated first and second metal structures 310, 320 are formed on the interlayer 230.

FIG. 1F shows the first metal structure 310 including, on the interlayer 230, a first metal wiring 318 connecting first contact structures 315 filling contact trenches 301 that expose first metal structures 311 as well as the second metal structures 320 including, on the interlayer 230, a second metal wiring 328 connecting second contact structures 325 filling contact trenches 301 exposing second metal structures 321.

FIG. 1G is a plan view illustrating the first metal wiring, which electrically connects the first metal structures 311 through the first contact structures 315, and the second metal wiring 328, which electrically connects the second metal structures 321 through the second contact structures 325.

Due to a vertical extension that is at least 20% or 50%, e.g., at least 100% greater than a vertical extension of the first and second metal structures 311, 321, the auxiliary structures 220 are effective as a template, which guides the etching of the contact trenches 301 to some degree, ensure a minimum distance between the first contact structures 315 and the second metal structures 321 as well as between the second contact structures 325 and the first metal structures 311 and ensure a lower limit value of a dielectric strength of an insulation between the first metal structures 311 and the second contact structures 325 as well as between the second metal structures 321 and the first contact structures 315. Alternatively, or in addition, the auxiliary structures 220 allow for a thicker interlayer 230 and/or for a greater admissible misalignment between the second mask openings 421 of FIG. 1D and the first mask openings 411 of FIG. 1A.

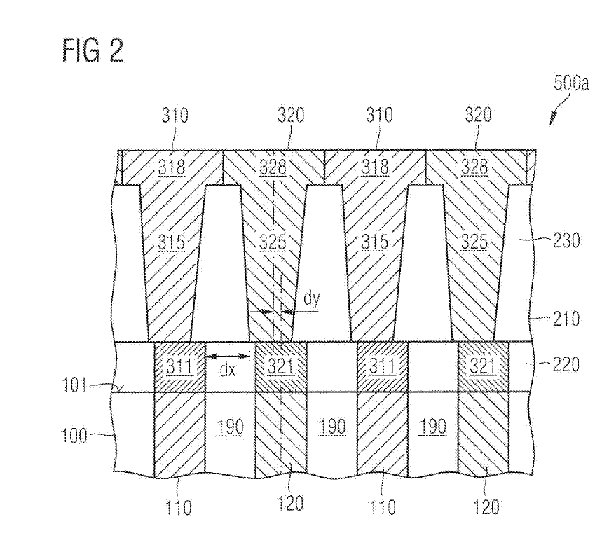

FIG. 2 shows a comparative example without auxiliary structure 220. The same misalignment dy of the second mask with regard to the first mask or the same misalignment of the first and second contact structures 315, 325 from their target positions results in a corresponding misalignment of the first and second contact structures 315, 325 with respect to the first and second metal structures 311, 321. The misalignment dy directly reduces a minimum distance dx between the first metal structures 311 and the second contact structures 325. The minimum distance decreases with increasing misalignment.

By contrast, as shown in FIG. 1F, the auxiliary structures 220 ensure that a minimum distance between the first metal structures 311 and the second contact structures 325 does not change as long as the misalignment dy does not exceed more than a half of the distance between neighboring first and second metal structures 311, 321. The effect can be used to further shrink the distance between first and second metal structures 311, 321 and between neighboring transistor cells and/or to increase the voltage difference applicable between the first and second conductive structures 110, 120.

The auxiliary structures 220 may fill the gaps 611 between neighboring layered stacks 610 completely. In the following embodiments, the auxiliary structures 220 are formed to fill only portions of the gaps 611 between neighboring layered stacks 610.

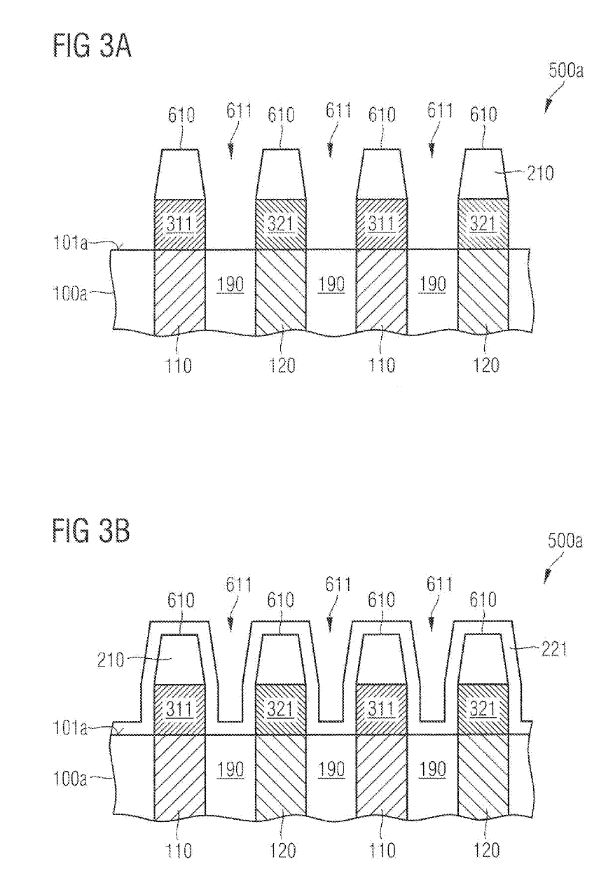

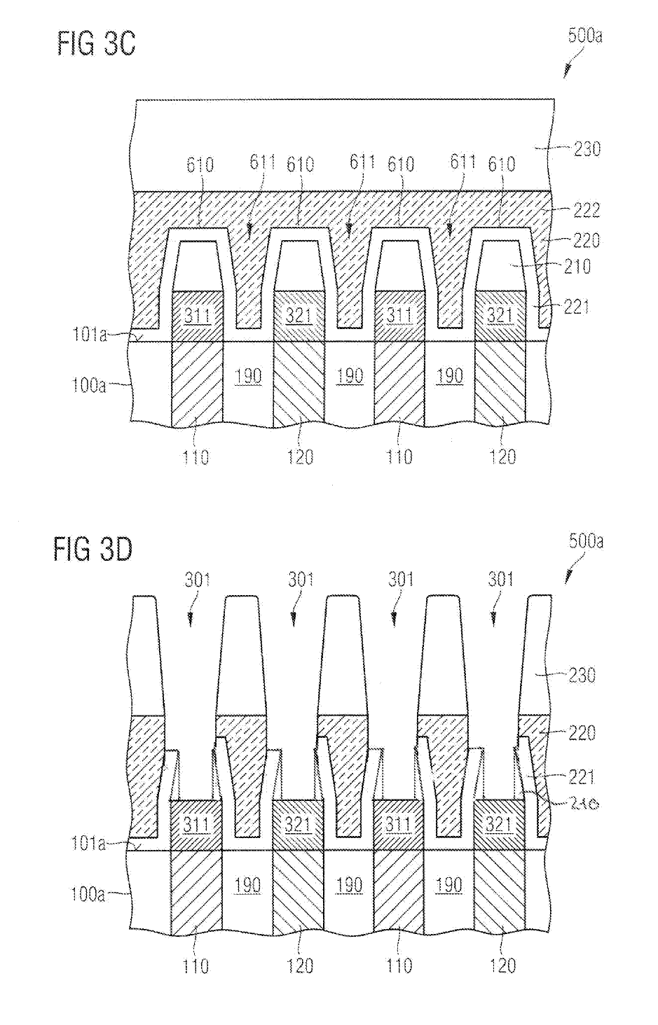

According to FIG. 3A, layered stacks 610 are formed from first portions of a layer stack 600 as described with reference to FIGS. 1A and 1B.

The caps 210 above the first and second metal structures 311, 321 may taper with increasing distance to the metal structures 311, 321. The taper angle may be adjusted by increasing an isotropic component of the etch process applied for etching the dielectric capping layer 210a of FIG. 1A.

A low-permittivity layer 221 may be deposited that partially fills the gaps 611 between the layered stacks 610. The low-permittivity layer 221 is of a dielectric material with a low permittivity εr of at most 4.5. The material of the low-permittivity layer 221 may be, for example, the same material as that of the caps 210.

In FIG. 3B the low-permittivity layer 221 is a conformal layer of a dielectric material such as silicon oxide, e.g., TEOS silicon oxide. A layer thickness of the low-permittivity layer 221 may be at most a third of the horizontal width of the gaps 611.

A second dielectric material with high etch selectivity against the first dielectric material is deposited. The second dielectric material may fill the remaining spaces between neighboring layered stacks 610 completely. According to an embodiment a deposition process deposits silicon nitride that fills the remaining spaces between the layered stacks 610 and that may also cover the layered stacks 610 covered by the low-permittivity layer 221.

An interlayer 230 of the first dielectric material or a third dielectric material is deposited onto a planar surface of the deposited second dielectric material.

FIG. 3C shows the low-permittivity layer 221 covering the layered stacks 610 and lining the gaps 611 between neighboring layered stacks 610. First portions of the second dielectric material between the layered stack 610 form the auxiliary structures 220. Second portions of the second dielectric material above the layered stacks 610 form a discontinuous etch stop layer 222. The interlayer 230 is formed on a planar surface of the etch stop layer 222.

Contact trenches 301 exposing the metal structures 311, 321 are formed, e.g., by a predominantly anisotropic etch process. With the etching of the interlayer 230 stopping at the etch stop layer 222, the etch process for the interlayer 230 is independent from a topography of the interlayer 230 and from different vertical extensions of the interlayer 230. Due to the high etch selectivity between the interlayer 230 and the etch stop layer 222 a long overetch of the interlayer 230 may compensate for different vertical extensions of the interlayer in various regions of the semiconductor substrate 500a. Etching the etch stop layer 222 may be time-controlled or may use a stop signal generated by exposing the low-permittivity layer 221. The thickness of the low-permittivity layer 221 may be comparatively uniform such that in case the low-permittivity layer 221 and the caps 210 are of different materials, e.g., different silicon oxides, the low-permittivity layer 221 may be etched through in a time-controlled etch process and after opening the caps 210 the etch process may change to an etch that is selective to the material of the low-permittivity layer 221. Since the etch stop layer 222, the low-permittivity layer 221 and the caps 210 show only low thickness variations, the concerned etch processes may be sufficiently defined by the etch time only. According to another embodiment the caps 210 and the low-permittivity layer 221 show only low etch selectivity and are etched through without change of the etch chemistry.

FIG. 3D shows the contact trenches 301 extending through the interlayer 230, the etch stop layer 222, the low-permittivity layer 221 and the caps 210. A misalignment of the contact trenches 301 from a target position that results in a misalignment of the bottom sections of the contact trenches 301 with regard to the metal structures 311, 321 does not exceed the thickness of the low-permittivity layer 221. On the other hand, the low-permittivity layer 221 ensures that a capacitive coupling between neighboring first and second metal structures 311, 321 is lower than in embodiments with the auxiliary structures 220 completely filling the gaps 611.

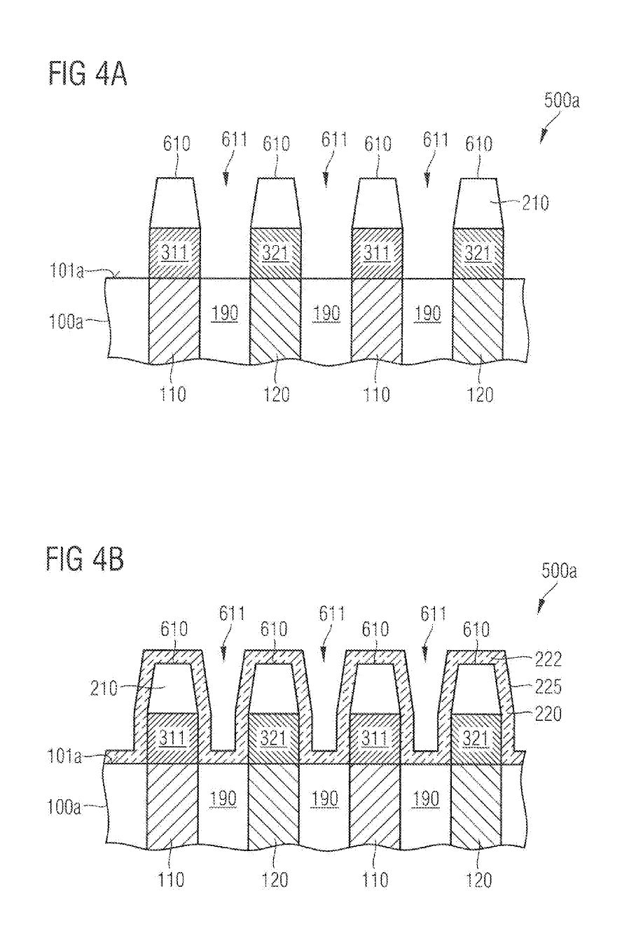

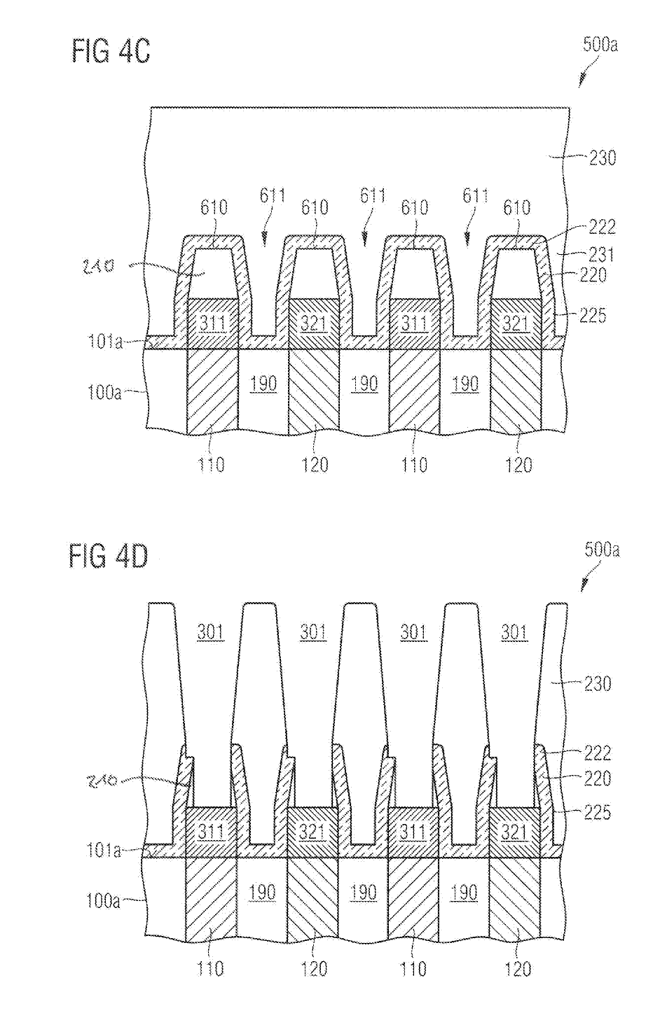

The embodiment of FIGS. 4A to 4D changes the sequence of deposition of the low-permittivity material and the second dielectric material forming the auxiliary structures 220.

FIG. 4A shows isolated layered stacks 610 in the vertical projection of the first and second conductive structures 110, 120 in the semiconductor substrate 500a.

An auxiliary layer 225 of the second dielectric material is deposited that covers the layered stacks 610 and that lines the gaps 611 between neighboring layered stacks 610.

FIG. 4B shows the auxiliary layer 225, which may be a conformal layer with a thickness less than half, for example at most a third of the distance between neighboring layered stacks 610.

First portions of the auxiliary layer 225 between the layered stacks 610 form an auxiliary structure 220 and second portions of the auxiliary layer 225 on top of the caps 210 form a discontinuous etch stop layer 222. A further dielectric material is deposited, which may be the first dielectric material of the caps 210 or a third dielectric material that can be etched with high selectivity against the second dielectric material of the auxiliary layer 225.

As shown in FIG. 4C first portions 231 of the further dielectric material fill remaining spaces between neighboring layered stacks 610 and a second portion of the further dielectric material forms the interlayer 230.

Contact trenches 301 are formed by using a second mask on the interlayer 230 as described with reference to FIGS. 1D to 1E. Forming the contact trenches 301 includes etching the interlayer 230 down to the discontinuous etch stop layer 222. After a sufficient over etch, the etch chemistry may switch to a composition that etches the second dielectric material of the auxiliary layer 225. After a certain etch time given by the thickness of the auxiliary layer 225, the etch chemistry changes again to etch the first dielectric material of the caps 210 with high selectivity against the second dielectric material of the auxiliary layer 225. Again, the auxiliary structure 220 guides the etching of the caps 210 as long as a misalignment does not exceed the thickness of the auxiliary layer 225 reduced by an amount resulting from the taper. According to another embodiment, the caps 210 do not taper and the etch stop layer 222 covers vertical sidewalls.

While in FIG. 3D the low-permittivity material covers sidewalls of the metal structures 311, 321 and the etch of the caps 210 may form pockets in the low-permittivity material along the sidewalls of the metal structures 311, 321, the second dielectric material, which is not recessed when the caps 210 are etched through, ensures that the etch reliably stops on the surface of the first and second metal structures 311, 321 and does not expose portions of the vertical sidewalls of the first and second metal structures 311, 321 as it may be the case in FIG. 3D, where the low-permittivity layer 221 may be of the same material as the cap 210. As a result, contact structures 315, 325 formed by filling the contact trenches 301 with conductive material can be formed more reliable.

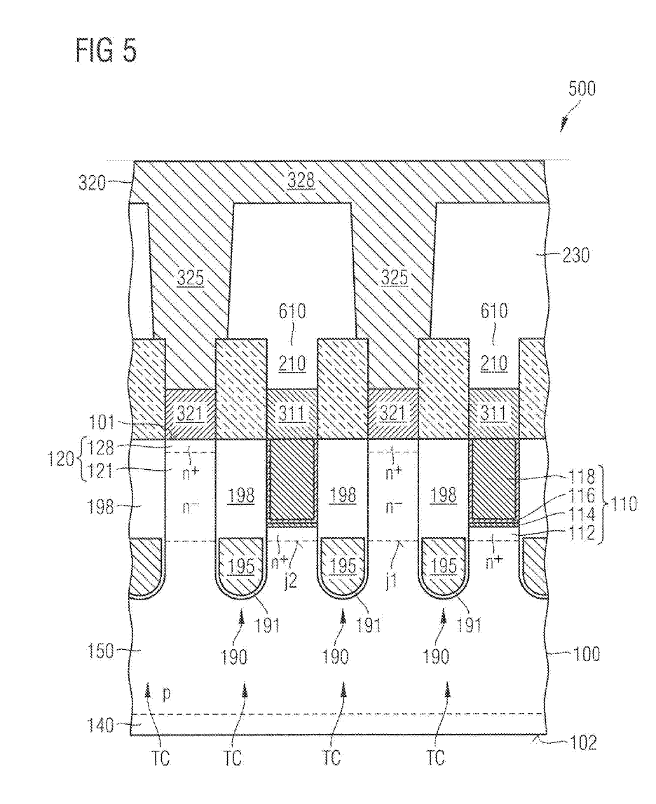

FIG. 5 shows a semiconductor device 500 including a plurality of transistor cells TC which are formed in a semiconductor portion 100 and which may extend along a horizontal direction perpendicular to the cross-sectional plane. Pairs of transistor cells TC may be arranged mirror-inverted such that two neighboring transistor cells TC may share a common source construction 110 or a common drain construction 120, respectively. The source and drain constructions 110, 120 of the transistor cells TC are formed side-by-side to each other along a second horizontal direction in the cross-sectional plane on opposite sides of trench electrode structures 190 extending from a first surface 101 into a semiconductor portion 100.

The drain construction 120 may include a heavily doped drain zone 128 with a dopant concentration sufficiently high to ensure an ohmic contact with second metal structures 312 formed on the first surface 101. The drain construction 120 may further include a weakly doped drift zone 121 forming a unipolar homojunction with the heavily doped drain zone 128 and a first j1 junction with a channel/body region 150. The channel/body region 150 may have the same conductivity type as the drift and the drain zones 121, 128 or may have the opposite conductivity type.

The source construction 110 may include a heavily doped source zone 112 forming a second junction j2, which may be a unipolar homojunction or a pn junction, with the channel/body zone 150. A contact layer 114 may directly adjoin the source zone 112. The contact layer 114 may contain or consist of a metal-semiconductor compound, e.g., a metal silicide, for example a titanium silicide TiSi layer with a thickness of at least 1 nm, e.g., at least 10 nm and at most 100 nm. The source construction 110 may further include a highly conformal tungsten layer 116 extending along the trench electrode structure 1990 and the contact layer 114. Another conductive material, for example coarse-grained tungsten, may form a fill portion 118 of the source construction 110.

The trench electrode structures 190 may include a conductive gate electrode 195 and a gate dielectric 191 dielectrically coupling the gate electrode 195 to adjoining portions of the channel/body regions 150. The trench electrode structures 190 may further include a dielectric fill portion 198 extending between a plane spanned by the first surface 101 and the homojunctions to the channel/body region 150. The semiconductor portion 100 may further include a heavily doped substrate portion 140 along a second surface 102 opposite to the first surface 101.

Auxiliary structures 220 are formed in the vertical projection of the trench electrode structures 190, wherein the width of the auxiliary structures 220 may be smaller or greater than the corresponding width of the trench electrode structures 190 such that the auxiliary structures 220 may on one side or on both side overlap with the source or drain constructions 110, 120. The auxiliary structures 220 may consist of or may include a main portion of silicon nitride, wherein the main portion extends at least from the interface between caps 210 and the metal structures 311, 312 to the upper edge of the caps 210.

A layered stack 610 is formed in the vertical projection of the source and drain structures 110, 120, wherein a horizontal width of the layered stacks 610 may be smaller or greater than a corresponding horizontal width of the source and drain constructions 110, 120 such that the layered stacks 610 may overlap at least at one side with the trench electrode structures 190.

The layered stacks 610 further include caps 210 of a first dielectric material, first metal structures 311 directly adjoining the source constructions 110, and second metal structures 321 directly adjoining the drain constructions 120. The material of the caps 210 may contain one or more deposited layers of silicon oxide, PSG, BSG, PBSG, FSG or polyimide.

An interlayer 230 covers the auxiliary structures 220 and the layered stacks 610. Second contact structures 325 extend from a surface of the interlayer 230 through the interlayer 230 and the caps 210 to the second metal structures 321 and a second metal wiring 328 on the interlayer 230 may connect the second contact structures 325. In another cross-sectional plane parallel to the illustrated cross-sectional plane first contact structures 315 may extend from the surface of the interlayer 230 through the interlayer 230 and the caps 210 to the first metal structures 311 and a first metal wiring 318 on the interlayer 230 may connect the first contact structures 315.

The auxiliary structures 220 define a minimum distance between the first contact structures 315 and the second metal structures 321 as well as between the second conductive structures 325 and the first metal structures 311.

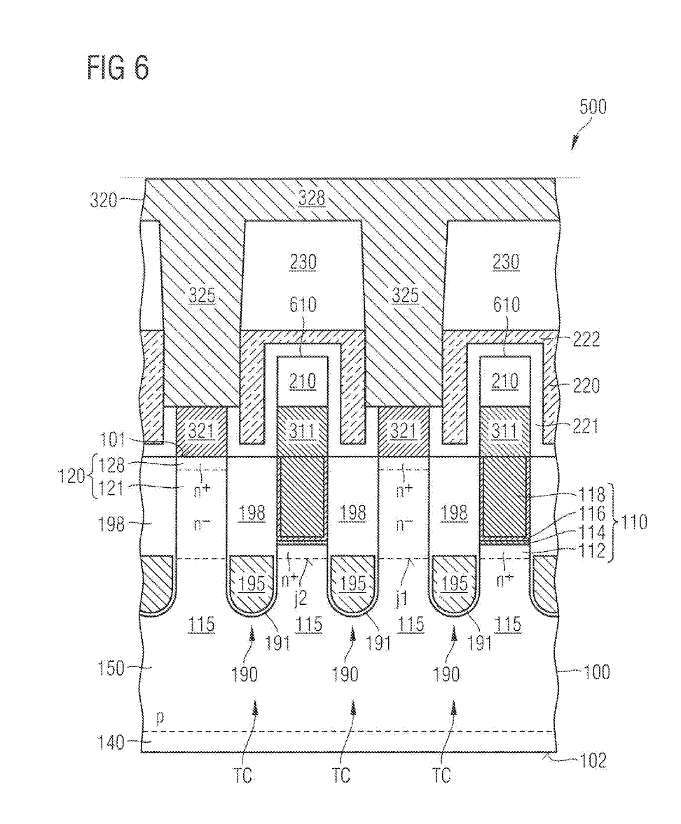

In FIG. 6 a low-permittivity layer 221 separates the auxiliary structures from the layered stacks 610 and decreases a capacitive coupling between the first and second metal structures 311, 321.

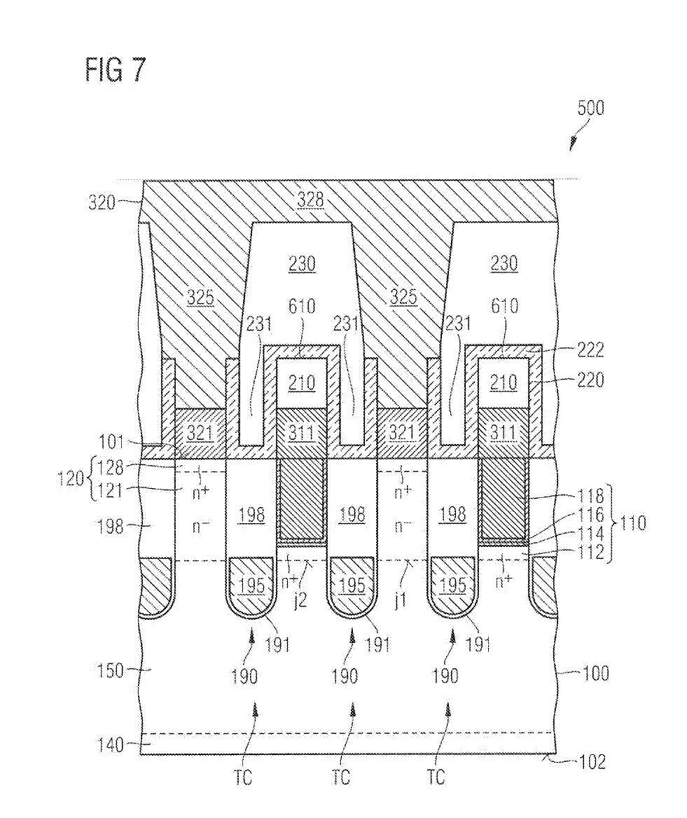

The semiconductor device of FIG. 7 shows a conformal auxiliary layer with first portions between the layered stacks 610 forming the auxiliary structures 220 and a second portion on the layered stacks 610 forming a discontinuous etch stop layer 222.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing a semiconductor device, the method comprising:
forming transistor cells in a semiconductor portion;
forming a layer stack on a main surface of a semiconductor layer, wherein the layer stack comprises a dielectric capping layer and a metal layer between the capping layer and the semiconductor layer;
removing second portions of the layer stack to form gaps between remnant first portions of the layer stack, wherein from the metal layer first metal structures that directly adjoin source constructions of the transistor cells and second metal structures are formed that directly adjoin drain constructions of the transistor cells;
forming auxiliary structures of a second dielectric material in the gaps;
forming an interlayer of the first or a third dielectric material, wherein the interlayer covers the auxiliary structures and the first portions; and
forming contact trenches extending through the interlayer and the capping layer to the first and second metal structures formed from remnant portions of the metal layer in the first portions of the layer stack, wherein the capping layer is etched selectively against the auxiliary structures.

2. The method of claim 1, wherein forming the contact trenches comprises etching the interlayer selectively against the auxiliary structures.

3. The method of claim 1, further comprising:
depositing a low-permittivity layer of a material with a lower permittivity than the second dielectric material before forming the auxiliary structures, wherein a thickness of the low-permittivity layer is less than half of a width of the gaps in the layer stack.

4. The method of claim 3, wherein forming the auxiliary structures comprises depositing the second dielectric material directly on the low-permittivity layer, wherein first portions of the deposited second dielectric material form the auxiliary structures and second portions of the deposited second dielectric material forms a discontinuous etch stop layer above the first portions of the layer stack and the auxiliary structures.

5. The method of claim 1, wherein the deposited second dielectric material is deposited directly on the first portions of the layer stack.

6. The method of claim 1, wherein the second dielectric material is deposited as conformal auxiliary layer, a thickness of the conformal layer is less than half of a width of the gaps in the layer stack, and portions of the auxiliary layer in the gaps form the auxiliary structures.

7. The method of claim 6, wherein the interlayer fills remaining voids in the gaps lined by the conformal layer.

8. The method of claim 1, wherein caps formed from the capping layer in the remnant first portions taper with increasing distance to the metal structures.

9. The method of claim 1, wherein the metal structures form parallel stripes.

10. The method of claim 1, further comprising:
forming transistor cells in the semiconductor portion prior to forming the layer stack.

11. A semiconductor device, comprising:
transistor cells;
separated layered stacks on a first surface of a semiconductor portion, each layered stack comprising a cap of a first dielectric material and a metal structure between the cap and the semiconductor portion, wherein the metal structure comprises first metal structures that directly adjoin to source constructions of the transistor cells and second metal structures that directly adjoin to drain constructions of the transistor cells;
auxiliary structures of a second, different dielectric material between neighboring layered stacks;
an interlayer of the first or a third, different dielectric material covering the layered stacks and the auxiliary structures; and
contact structures extending through the interlayer and the caps to the metal structures in the layered stacks, wherein between neighboring auxiliary structures the contact structures comprise bottom sections that extend through the caps, respectively.

12. The semiconductor device of claim 11, wherein at least some of the contact structures directly adjoin to one of the neighboring auxiliary structures.

13. The semiconductor device of claim 11, wherein the interlayer has a planar surface.

14. The semiconductor device of claim 11, further comprising:
a low-permittivity layer between the layered stacks and the auxiliary structures, wherein a permittivity o the low-permittivity layer is lower than a permittivity of the second dielectric material.

15. The semiconductor device of claim 14, wherein a thickness of the low-permittivity layer is less than half of a width of the gaps between the layered stacks.

16. The semiconductor device of claim 11, wherein first portions of a conformal auxiliary layer form the auxiliary structures.

17. The semiconductor device of claim 16, wherein a thickness of the conformal auxiliary layer is less than a third of a width of the gaps.

18. The semiconductor device of claim 16, wherein the first or third dielectric material of the interlayer fills a remaining gap between neighboring layered stacks covered by the conformal auxiliary layer.

19. The semiconductor device of claim 11, wherein the second dielectric material is silicon nitride.
